(19) United States
(12) Patent Application Publication
(10) Pub. No.: US 2022/0216170 A1
(43) Pub. Date: Jul. 7, 2022

(54) METHOD FOR PRINTING SOLDER ONTO A WAFER AND SYSTEM THEREOF

(71) Applicant: Inari Technology Sdn Bhd, BAYAN LEPAS (MY)

(72) Inventor: BOON SENG TEOH, BAYAN LEPAS (MY)

(73) Assignee: Inari Technology Sdn Bhd, BAYAN LEPAS (MY)

(21) Appl. No.: 17/565,076

(22) Filed: Dec. 29, 2021

(30) Foreign Application Priority Data
Jan. 6, 2021 (MY) PI2021000051

(51) Int. Cl. H01L 23/00

(52) U.S. Cl. CPC H01L 24/11; H01L 24/742; H01L 2224/117; H01L 2224/1181; H01L 2224/11849

(57) ABSTRACT

A method for printing solder onto a wafer (101) including the steps of depositing solder paste (102) onto a wafer (101), applying an inline reflow process to the deposited solder paste (102) to form solder bumps (103) on the wafer (101), and cleaning the reflowed solder bumps (103). The method for printing solder onto the wafer (101) is based on a system thereof that includes a wafer solder printer (1), an inline reflow means (2) and a de-fluxing means (3), wherein each step has its parameters optimized by means of a staging process control.

### CROSS-REFERENCE TO RELATED APPLICATION

The instant application claims priority to Malaysia Patent Application Serial No. PI202100051 filed Jan. 6, 2021, the entire specification of which is expressly incorporated herein by reference.

### FIELD OF THE INVENTION

The present invention relates to a method for printing solder onto a wafer, particularly with optimized parameters in a staging process control employed therewith to achieve a substantially high yield within a predetermined period.

### BACKGROUND OF THE INVENTION

Presently, in a wafer-level circuit and components assembly industry, solder printing techniques utilize one stencil to print solder paste on a wafer top surface or to fill through holes in the wafer with solder material. Because a vertical depth of the through holes is much greater than a low height of a solder pad printed on a surface of the wafer, the stencil is expensive and complex to fabricate and then use. It is also time consuming to use the stencil during wafer-level solder patterning because it takes longer to fill a through hole with solder than to print a thin solder pad on the surface of the wafer. Attempts to speed up the process leave solder patterns that are located imprecisely or through holes that have an inadequate amount of solder.

Many technologies related to solder printing have been proposed to improve the system. For example, a publication by Kay et al. titled “Stencil Printing Technology for Wafer Level Bumping at sub-100 Micron Pitch Using Pb-Free Alloys” discloses a solder paste printing process at sub-100 μm pitch using Pb-free solder paste with IPC type-6 (15-5 μm) particle size distributions. The results from the study confirm that consistent sized paste deposits can be produced onto wafers at ultra-fine pitch geometries using a stencil printing process. It is also disclosed that the solder paste deposit can be controlled by selecting different shapes of stencil apertures, in which print consistency and uniformity of the solder bumps generated are also governed by the volume of solder paste for each deposit. Besides that, a United States patent with publication no. U.S. Pat. No. 5,740,730A discloses a method and apparatus for forming adhesive and solder pads on a printed circuit board to surface mount electrical components to the board. A solder paste is deposited onto the printed circuit board through a first stencil that has a plurality of first openings. The solder paste then forms a plurality of solder pads on the board. Further, a second stencil is then positioned on the printed circuit board, the second stencil having a plurality of second openings and a recess in its bottom face configured to receive the plurality of solder pads. After the second stencil is positioned on the printed circuit board, an adhesive material is deposited onto the board through the second openings of the second stencil to form a plurality of adhesive pads on the board.

Another United States patent with publication no. U.S. Pat. No. 5,996,488A discloses a method of producing a substrate for an electron source, the substrate including a plurality of electron emission devices, each including a pair of opposing electrodes, the plurality of electron emission devices being arranged on the substrate. The method comprises the steps of preparing an intaglio plate having recessed portions corresponding to a pattern of the electrodes, the depth of the recessed portions with ink, pressing a blanket against the intaglio plate so that the ink is transferred from inside of the recessed portions onto the blanket, and bringing the blanket into contact with the substrate so that the ink is transferred from the blanket onto the substrate thereby forming the electrode pattern thereon.

Another technology as disclosed in a United States patent with publication no. U.S. Pat. No. 6,443,059B1 recites a solder screen printing process comprising the steps of providing a wafer having a plurality of chips thereon, and a passivation layer covering the chips, wherein the bonding pads have a plurality of under bump metal (UBM) structures formed thereon; forming a pattern layer on the wafer, wherein the pattern layer has a plurality of first openings that defines the locations on the chips where bumps are to be subsequently formed; providing a carrier that has a wafer mounting location, providing a mounting support means that is mounted on the carrier, wherein the mounting support means has a second opening of the wafer size, such that the wafer mounting location of the carrier is exposed through the second opening; mounting the wafer on the carrier through the second opening of the mounting support means; and filling the first openings with a solder paste.

### SUMMARY OF THE INVENTION

It is an object of the present invention to provide a staging process control with optimized parameters to achieve a substantially high yield over a predetermined period. It is also an object of providing these optimized parameters for every stage in the wafer solder printing process flow to enable a higher efficiency and productivity in manufacturing semiconductor articles.

In one aspect of the invention, there is provided a method for printing solder onto a wafer comprising the steps of depositing solder paste onto the wafer, by a wafer solder printer, applying an inline reflow process to the deposited solder paste to form solder bumps on the wafer, by an inline reflow means, and cleaning the reflowed solder bumps, by a de-fluxing means wherein each step has its parameters optimized by means of a staging process control.

Preferably, the method further includes a step of inspecting the solder bumps.

Preferably, the staging process control is employed to achieve a target yield of substantially 99% to 99.5% within a maximum operating time of substantially 7 hours.

Preferably, the wafer solder printer deposits the solder paste at speed range from substantially 30 mm/s to 40 mm/s.

Preferably, the wafer solder printer uses a squeegee for applying pressure ranging from substantially 6 kg to 8 kg onto the deposited solder paste.

Preferably, the cleaning of the solder bumps is done using a de-fluxing means.

Preferably, the wafer is loaded into the de-fluxing means at predetermined intervals during cleaning.

Preferably, the de-fluxing means operates at a temperature range of substantially 50° C. to 120° C.

Preferably, the solder bumps are inspected using a three-dimensional automated optical inspection (AOI) mean and by X-ray means.

In another aspect of the invention, there is also provided a system for printing solder onto a wafer comprising: a wafer solder printer for depositing solder paste onto a wafer, an inline reflow means for applying an inline reflow process to the deposited solder paste to form solder bumps on the wafer, and a de-fluxing means for cleaning the solder bumps, wherein the system executes a method as described above with parameters that are optimized by means of a staging process control.

Preferably, the staging process control is employed to achieve a target yield of substantially 99% to 99.5% within a maximum operating time of substantially 7 hours.

Preferably, the solder bumps are inspected by means of a three-dimensional (3D) automated optical inspection (AOI) means and by X-ray means.

One skilled in the art will readily appreciate that the present invention is well adapted to carry out the objects and obtain the ends and advantages mentioned, as well as those inherent therein. The embodiment described herein is not intended as limitations on the scope of the invention.

### BRIEF DESCRIPTION OF THE DRAWINGS

For the purpose of facilitating an understanding of the invention, there is illustrated in the accompanying drawing the preferred embodiments from an inspection of which when considered in connection with the following description, the invention, its construction and operation and many of its advantages would be readily understood and appreciated.

FIG. 1 is a block diagram illustrating a method for printing solder onto a wafer.

FIG. 2 illustrates an exemplary embodiment of the method for printing solder onto the wafer.

FIG. 3 illustrates an exemplary embodiment of depositing solder paste onto the wafer.

### DETAILED DESCRIPTION OF THE INVENTION

Hereinafter, the invention shall be described according to the preferred embodiments of the present invention and by referring to the accompanying description and drawings. However, it is to be understood that limiting the description to the preferred embodiments of the invention is merely to facilitate discussion of the present invention and it is envisioned that those skilled in the art may devise various modifications without departing from the scope of the appended claim.

The invention will now be described in greater detail, by way of example with reference to the drawings.

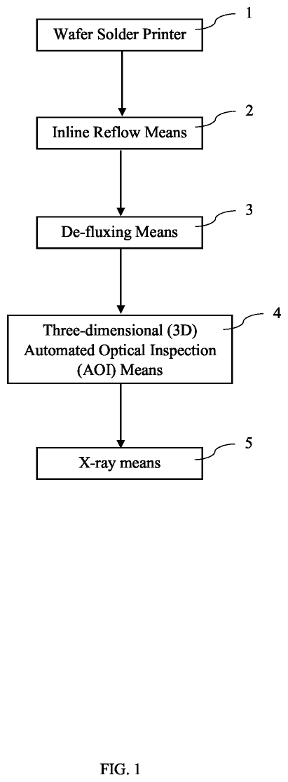

FIG. 1 is a block diagram illustrating a system for printing solder onto a wafer 101, the system comprising a wafer solder printer 1 configured to deposit solder paste 102 onto the wafer. Solder paste 102 is a mixture of minute solder spheres held within a specialised form of solder flux, the mixture having a texture of a paste. The object of the printer 1 is to accurately deposit a correct amount onto each pad on the wafer 101 to be soldered. This is achieved by screen-printing the solder paste 102, preferably through a stencil 103, but alternatively can also be applied by jet printing. The system further comprises an inline reflow means 2 for applying an inline reflow process on the deposited solder paste 102 to form solder bumps 104 on the wafer 101, wherein the inline reflow means 2 is preferably a reflow oven. The inline reflow process is a process in which the solder paste 102 is used to temporarily attach a plurality of miniscule electrical components to their contact pads, after which the entire assembly is subjected to controlled heat. The goal of the reflow process is for the solder paste 102 to reach a eutectic temperature at which the solder paste 102 undergoes a phase change to a liquid or molten state, wherein the molten solder paste demonstrates properties of adhesion, creating permanent solder joints between the electrical components and the wafer 101.

In a preferred embodiment, the system includes a de-flux means 3 for cleaning the solder bumps 104 formed during the inline reflow process. De-fluxing is a cleaning process designed to not only remove solder flux residue and by-products from the wafer 101, but also remove impurities such as solder balls, dirt, dust, organic materials, and other contaminants. Traces of flux material which remains on the wafer 101 after solder printing must be completely removed as these may cause permanent failure in circuitry through corrosion, absorption of water and other effects. Preferably, de-fluxing involves washing a surface of the wafer 101 with a solvent which is capable of dissolving the flux residue prior to having the wafer 101 being rinsed with water and dried.

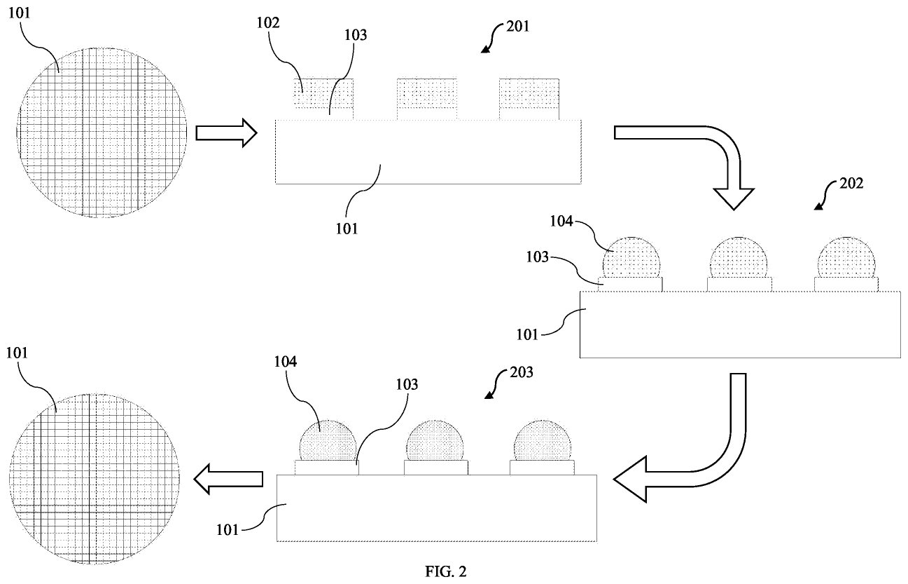

Besides that, the system further includes a three-dimensional (3D) automated optical inspection (AOI) means 4 and an X-ray means 5 for inspecting the solder bumps 104 on the wafer 101 upon completion of the de-fluxing process. The 3D AOI means 4 operates to inspect and detect solder bump 104 detects which may include smears, coin, smashed solder bumps 104, insufficient solder volume, small or large solder bumps 104, oxidation, or the likes. The 3D AOI means 4 may further inspect and/or detect flux residue on surface of the solder bumps 104. In a particular embodiment, the X-ray means 5 may be able to inspect both small and large solder bumps 104 volumes, and also detect solder bump 104 voids which are substantially 25% of the individual solder bump 104 size. Further, the key parameters for each machine in the system will be discussed further herein with reference to FIG. 2.

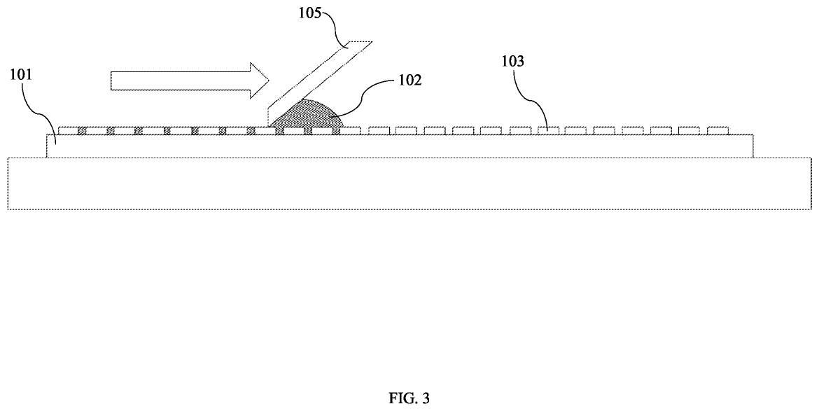

FIG. 2 is a flow chart illustrating a method for printing solder onto the wafer 101 based on the above-mentioned system. Firstly, the wafer 101 is loaded into the wafer solder printer 1. At Step 201, a stencil is placed on top of the wafer 101 and solder paste 102 is subsequently printed onto said wafer 101 by using a squeegee 105, such as illustrated in FIG. 3. Preferably, the stencil 103 may be substantially 100 μm in diameter with a 175 μm pitch, and aperture spacing of substantially 25 μm to 75 μm in between each aperture. The squeegee 105 is a tool used to apply necessary force required to move the solder paste 102 across the stencil 103 and on to the wafer 101, in which the squeegee 105 may be made from metal and/or polyurethane. The solder printing process deposits the solder paste 102 onto the wafer 101 preferably at a print speed ranging from substantially 30 mm/s to 40 mm/s with the squeegee 105 blade applying a pressure at substantially 6 kg to 8 kg. During the print cycle, sufficient pressure across the entire length of the squeegee 105 is required to ensure a clean wipe of the stencil 103. Too little pressure can cause “smearing” of the solder paste 102 on the stencil 103, poor deposition, and an incomplete transfer to the wafer 101. Too much pressure can cause “scooping” of the solder paste 102 from larger apertures, excess wear on the stencil 103 and the squeegee 105, and may cause “bleeding” of the solder paste 102 between the stencil 103 and the wafer 101. Another key parameter to be noted is an angle of the squeegee 105 when applying the solder paste 102 onto the stencil 103 and wafer 101. The angle of the squeegee 103 is also preferably set to 60° by holders that the squeegee 105 is fixed to. If the angle is increased, it can cause “scooping” of the solder paste 102 from the stencil 103 apertures, causing less solder paste 102 to be deposited onto the wafer 101. However, if the angle is reduced, it can cause a residue of solder paste 102 to be left on the stencil 103 after the squeegee 105 has completed the print.

In a preferred embodiment, the solder printing process operates for a maximum of substantially 7 hours, wherein a staging process control with optimized parameters is employed within the 7 hours. Preferably, viscosity of the solder paste 102 is firstly checked so that said solder paste 102 do not cling onto the squeegee 105. Further, the solder paste 102 is kneaded onto the stencil 103 in a backward and forward motion until the solder paste 102 reaches a desired viscosity. Once the solder paste 102 has reached a desired viscosity, the printing process will commence by depositing the solder paste 102 into the apertures of the stencil 103 uniformly across the wafer 101. Within the substantially 7 hours of operation, consistency of the solder paste 102 may be examined to ensure performance of the printer 1 is at optimum efficiency.

At Step 202, the wafer 101 is then loaded into the inline reflow means 2 wherein the solder paste 102 residue on top of the wafer 101 are formed into solder bumps 104. The inline reflow system 2 comprises a plurality of reflow sections, preferably 9, with a control temperature of substantially 250° C. to fully cure the solder bumps 104. Preferably, the wafer 101 is heated at a predetermined rate to ensure that no defects such as components cracking or the solder paste 102 splattering during the reflow process. Further, oxygen levels in the inline reflow means 2 may also be controlled to operate at a minimum of substantially 75 parts per million (PPM) for a complete reflow cycle. Each solder bump 104 may have a bump height of substantially 45 μm to 55 μm, diameter ranging from substantially 90 μm to 110 μm, and a maximum solder bump 104 co-planarity of substantially 10 μm.

At Step 203, the wafer 101 is loaded into the de-fluxing means 3 for cleaning. In a preferred embodiment, the de-fluxing means 3 requires the wafer 101 to be loaded into said de-fluxing means 3 at predetermined intervals during the cleaning process. Once loaded in, active wafer 101 surfaces are required to be faced down during the cleaning, such that all flex residues or chemical substances on the active wafer 101 surfaces will be rinsed off with the help of gravity. Some of the characteristics/parameters of the cleaning process include a wash fixture turning speed of substantially 60 to 80 RPM for substantially 3 to 5 seconds, temperatures ranging from substantially 50° C. to 120° C., a wash cycle of at least substantially 25 to 60 cycles, a chemical concentration of substantially 13% to 20%; and a reservoir stirring time of substantially 800 to 1000 seconds with pre-heat temperature to promote chemical reaction in the reservoir and cleaning effectiveness on the wafer 101.

In another preferred embodiment, the dried wafer 101 is transferred to the 3D AOI means 4 and the X-ray means 5 for further inspection before being transferred to the next station in the production line. Particularly, the 3D AOI means 4 inspect several criteria which include Average Bump Height (ABH) performance from substantially 40 to 65 μm across the entire wafer 101, solder bump 104 defects detection and flux residue detection on the wafer 101 surface. The solder bump 104 defects may include smear, coin, smash, insufficient solder volume, small, large, and oxidation or the likes. However, the X-ray means 5 inspect criteria, such as solder bump 104 void, for up to substantially 25% of the solder bump 104 size, small and large solder bump 104 volume, and solder bump 104 traceability.

The present disclosure includes as contained in the appended claims, as well as that of the foregoing description. Although this invention has been described in its preferred form with a degree of particularly, it is understood that the present disclosure of the preferred form has been made only by way of example and that numerous changes in the details of construction and the combination and arrangements of parts may be resorted to without departing from the scope of the invention.

What is claimed is:

1. A method for printing solder onto a wafer, comprising the steps of:
depositing solder paste onto the wafer, by a wafer solder printer;
applying an inline reflow process to the deposited solder paste to form solder bumps on the wafer, by an inline reflow means; and
cleaning the reflowed solder bumps, by a de-fluxing means;
wherein each step has its parameters optimized by means of a staging process control.

2. The method according to claim 1, further comprising the step of inspecting the solder bumps.

3. The method according to claim 2, wherein the staging process control is employed to achieve a target yield of substantially 99% to 99.5% within a maximum operating time of substantially 7 hours.

4. The method according to claim 3, wherein the wafer solder printer deposits the solder paste at speed range from substantially 30 mm/s to 40 mm/s.

5. The method according to claim 4, wherein the wafer solder printer uses a squeegee for applying pressure ranging from substantially 6 kg to 8 kg onto the deposited solder paste.

6. The method according to claim 5, wherein the cleaning of the solder bumps is done using a de-fluxing means.

7. The method according to claim 6, wherein the wafer is loaded into the de-fluxing means at predetermined intervals during cleaning.

8. The method according to claim 7, wherein the de-fluxing means operates at a temperature range of substantially 50° C. to 120° C.

9. The method according to claim 8, wherein the solder bumps are inspected using a three-dimensional (3D) automated optical inspection (AOI) means and by X-ray means.

10. A system for printing solder onto a wafer, comprising:
a wafer solder printer for depositing solder paste onto a wafer;
an inline reflow means for applying an inline reflow process to the deposited solder paste to form solder bumps on the wafer; and
a de-fluxing means for cleaning the solder bumps;
wherein the system executes a method according to claim 1 with parameters that are optimized by means of a staging process control.

11. The system according to claim 10, wherein the staging process control is employed to achieve a target yield of substantially 99% to 99.5% within a maximum operating time of substantially 7 hours.

12. The system according to claim 11, wherein the solder bumps are inspected by means of a three-dimensional (3D) automated optical inspection (AOI) means and by X-ray means.
